(19) United States
(12) Patent Application Publication
(10) Pub. No.: US 2025/0210542 A1
(43) Pub. Date: Jun. 26, 2025

(54) SEMICONDUCTOR PACKAGE

(71) Applicant: SAMSUNG ELECTRONICS CO., LTD., Suwon-si (KR)

(72) Inventor: Wooyeol LEE, Suwon-si (KR)

(73) Assignee: SAMSUNG ELECTRONICS CO., LTD., Suwon-si (KR)

(21) Appl. No.: 18/753,437

(22) Filed: Jun. 25, 2024

(30) Foreign Application Priority Data
Dec. 26, 2023 (KR) 10-2023-0191125

(51) Int. Cl. H01L 23/00; H01L 23/31; H01L 23/498

(52) U.S. Cl. CPC H01L 23/562; H01L 23/3128; H01L 23/49816; H01L 24/08; H01L 24/48; H01L 2224/08145; H01L 2224/08225; H01L 2224/48145; H01L 2224/48227; H01L 2924/01029; H01L 2924/15311; H01L 2924/182; H01L 2924/35

(57) ABSTRACT

A semiconductor package includes a substrate including an inner layer wiring structure including an insulating layer and a wiring layer, a first protective layer on a first surface of the inner layer wiring structure, a second protective layer on a second surface of the inner layer wiring structure that is opposite to the first surface of the inner layer wiring structure, and a first warpage reduction member and a second warpage reduction member on the first protective layer, a semiconductor chip above the first protective layer and connected to the substrate, and a molding material encapsulating the semiconductor chip, where the first warpage reduction member is on a first side surface of the substrate, and the second warpage reduction member is on a second side surface of the substrate, the second side surface being opposite to the first side surface.

### CROSS-REFERENCE TO RELATED APPLICATION

This application is based on and claims priority to Korean Patent Application No. 10-2023-0191125, filed on Dec. 26, 2023, in the Korean Intellectual Property Office, the disclosure of which is incorporated by reference in its entirety.

### BACKGROUND

Example embodiments of the disclosure relate to a semiconductor package.

A warpage phenomenon in which a semiconductor package is bent or twisted frequently occurs due to a difference in a coefficient of thermal expansion (CTE) between components in the semiconductor package, such as a substrate, a semiconductor chip, a molding material, and or the like. The warpage phenomenon may cause a non-wet defect in which a solder ball disposed at a lower semiconductor package constituting a package on package (POP) or a lower side of the semiconductor package is not connected to the substrate on which the package is mounted. Because the non-wet defect of the semiconductor package also affects performance and reliability of the package, a method for preventing the non-wet defect by controlling warpage of the semiconductor package is required.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a semiconductor package capable of improving a mounting defect of the package and improving reliability by preventing or controlling warpage.

One or more example embodiments provide a semiconductor package capable of minimizing transfer of a crack generated outside the package to the inside of the package.

Additional aspects will be set forth in part in the description which follows and, in part, will be apparent from the description, or may be learned by practice of the presented embodiments.

According to an aspect of an example embodiment, a semiconductor package may include a substrate including an inner layer wiring structure including an insulating layer and a wiring layer, a first protective layer on a first surface of the inner layer wiring structure, a second protective layer on a second surface of the inner layer wiring structure that is opposite to the first surface of the inner layer wiring structure, and a first warpage reduction member and a second warpage reduction member on the first protective layer, a semiconductor chip above the first protective layer and connected to the substrate, and a molding material encapsulating the semiconductor chip, where the first warpage reduction member is on a first side surface of the substrate, the second warpage reduction member is on a second side surface of the substrate, the second side surface being opposite to the first side surface, and the first protective layer is at least partially covered by the molding material on a third side surface of the substrate and a fourth side surface of the substrate, the fourth side surface being opposite to the third side surface.

According to an aspect of an example embodiment, a semiconductor package may include a substrate including an inner layer wiring structure including an insulating layer and a wiring layer, at least one warpage reduction member above a first surface of the inner layer wiring structure, a first protective layer on the first surface of the inner layer wiring structure and at least partially covering the at least one warpage reduction member, and a second protective layer on a second surface of the inner layer wiring structure that is opposite to the first surface of the inner layer wiring structure, a semiconductor chip above the first protective layer and connected to the substrate, and a molding material that encapsulates the semiconductor chip, where the at least one warpage reduction member is at an edge region of the substrate.

According to an aspect of an example embodiment, a semiconductor package may include a substrate including an inner layer wiring structure including an insulating layer and a wiring layer, at least one warpage reduction member above a first surface of the inner layer wiring structure, and conductive bumps above the first surface of the inner layer wiring structure and connected to the wiring layer, a semiconductor chip above a second surface of the inner layer wiring structure that is opposite to the first surface of the inner layer wiring structure, the semiconductor chip connected to the substrate, and a molding material encapsulating the semiconductor chip, where the at least one warpage reduction member is at an edge region of the substrate.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a cross-sectional view illustrating a semiconductor package according to one or more embodiments;

FIG. 2 is a plan view illustrating a layout of a warpage reduction member according to one or more embodiments;

FIG. 3 is a diagram illustrating a warpage direction of the semiconductor package including the warpage reduction member having the layout of FIG. 2 according to one or more embodiments;

FIG. 4 is a plan view illustrating a layout of a warpage reduction member according to one or more embodiments;

FIG. 5 is a plan view illustrating a layout of a warpage reduction member according to one or more embodiments;

FIG. 6 is a diagram illustrating a warpage direction of a semiconductor package including a warpage reduction member having the layout of FIG. 5 according to one or more embodiments;

FIG. 7 is a plan view illustrating a layout of a warpage reduction member according to one or more embodiments;

FIG. 8 is a plan view illustrating a layout of a warpage reduction member according to one or more embodiments;

FIG. 9 is a plan view illustrating a layout of a warpage reduction member according to one or more embodiments;

FIG. 10 is a cross-sectional view illustrating a semiconductor package according to one or more embodiments;

FIG. 11 is a cross-sectional view illustrating a semiconductor package according to one or more embodiments;

FIG. 12 is a cross-sectional view illustrating a semiconductor package according to one or more embodiments; and

FIGS. 13 to 15 are plan views illustrating process of forming the warpage reduction member according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Further, in the drawings, the size and thickness of each element are arbitrarily illustrated for ease of description, and the present disclosure is not necessarily limited to those illustrated in the drawings. In the drawings, the thicknesses of layers, films, panels, regions, areas, etc., are exaggerated for clarity. In the drawings, for ease of description, the thicknesses of some layers and areas are exaggerated.

Throughout the specification, when a part is “connected” to another part, it includes not only a case where the part is “directly connected” but also a case where the part is “indirectly connected” with another part in between. In a similar sense, this includes being “physically connected” as well as being “electrically connected”. In addition, unless explicitly described to the contrary, the word “comprise” and variations such as “comprises” or “comprising” will be understood to imply the inclusion of stated elements but not the exclusion of any other elements.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

Additionally, throughout the specification, a singular reference to a component includes references to a plurality of these components, unless specifically stated to the contrary. For example, “an insulating layer” may be used to indicate not only one insulating layer but also a plurality of insulating layers such as two, three, or more insulating layers.

In addition, throughout the specification, references to one surface and the other surface are intended to distinguish different surfaces from each other, and are not necessarily intended to be limited to a specific surface. Accordingly, a surface referred to as one surface in a specific portion of the specification may be referred to as the other surface in another portion of the specification.

Hereinafter, a semiconductor package according to one or more embodiments of the present disclosure will be described with reference to the drawings.

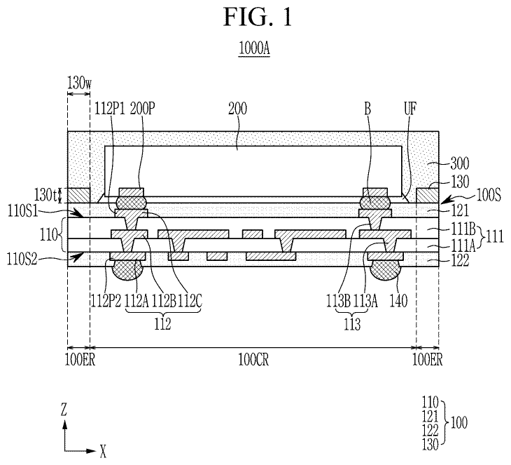

FIG. 1 is a cross-sectional view illustrating a semiconductor package according to one or more embodiments.

Referring to FIG. 1, the semiconductor package 1000A may include a substrate 100, a semiconductor chip 200 disposed above the substrate 100 to be electrically connected to the substrate 100, and a molding material 300 disposed on the substrate 100 and encapsulating the semiconductor chip 200.

The substrate 100 may have a central region 100CR and an edge region 100ER surrounding the central region 100CR. The edge region 100ER may include a side surface 100S of the substrate 100. In one or more embodiments, the central region 100CR and the edge region 100ER of the substrate 100 may not have a distinct boundary, and the regions may be referred as such to describe a region where a warpage reduction member 130 described later is disposed.

In addition, the substrate 100 may include an inner layer wiring structure 110 having a first surface 110S1 and a second surface 110S2, a first protective layer 121 disposed on the first surface 110S1 of the inner layer wiring structure 110, a second protective layer 122 disposed on the second surface 110S2 of the inner layer wiring structure 110, and at least one warpage reduction member 130 disposed on the first protective layer 121.

The inner layer wiring structure 110 may include one or more insulating layers 111 and one or more wiring layers 112. For example, the inner layer wiring structure 110 may include a first insulating layer 111A, a first wiring layer 112A and a second wiring layer 112B, a second insulating layer 111B disposed on the first insulating layer 111A to cover the second wiring layer 112B, and a third wiring layer 112C disposed on the second insulating layer 111B.

Additionally, the inner layer wiring structure 110 may include vias 113 for electrically connecting the wiring layers 112 disposed at different layers. For example, the inner layer wiring structure 110 may include first vias 113A penetrating the first insulating layer 111A to electrically connect the first wiring layer 112A and the second wiring layer 112B, and second vias 113B penetrating the second insulating layer 111B to electrically connect the second wiring layer 112B and the third wiring layer 112C.

An insulating material such as a prepreg or the like may be used as a material of the insulating layer 111, and a conductive material such as copper (Cu), aluminum (Al), or the like may be used as a material of each of the wiring layers 112 and the vias 113.

The third wiring layer 112C disposed on the first surface 110S1 may have a first connection pad 121P1 electrically connected to the semiconductor chip 200, and the first wiring layer 112A disposed on the second surface 110S2 may have a second connection pad 121P2 where a conductive bump 140 is disposed.

The first protective layer 121 may be disposed on a first surface of the inner layer wiring structure 110, and the second protective layer 122 may be disposed on a second surface of the inner layer wiring structure 110 to physically, mechanically, and/or chemically protect the inner layer wiring structure 110. For example, the first protective layer 121 and the second protective layer 122 may be a solder resist.

The first protective layer 121 may have an opening that exposes a first connection pad 112P1, and a conductive bump B may be disposed on the first connection pad 112P1 that is exposed through the opening of the first protective layer 121. Similarly, the second protective layer 122 may have an opening that exposes a second connection pad 112P2, and the conductive bump 140 may be disposed on the second connection pad 112P2 that is exposed through the opening of the second protective layer 122.

At least one warpage reduction member 130 may be disposed at the edge region 100ER of the substrate 100. The warpage reduction member 130 may form the side surface 100S of the substrate 100 together with the insulating layer 111 of the inner layer wiring structure 110, the first protective layer 121, and the second protective layer 122. The insulating layer 111 of the inner layer wiring structure 110, the first protective layer 121, and the second protective layer 122 may extend from the central region 100CR of the substrate 100 to the edge region 100ER, such that the insulating layer 111 of the inner layer wiring structure 110, the first protective layer 121, and the second protective layer 122 are disposed across an entire region of the substrate 100.

Exemplary layouts of the warpage reduction member 130 will be described later.

In one or more embodiments, a coefficient of thermal expansion of the warpage reduction member 130 may be 5 to 150 ppm/° C.

In one or more embodiments, the warpage reduction member 130 with a relatively high coefficient of thermal expansion may be used, such that the semiconductor package 1000A having a tendency to warp in a specific direction may be formed using a property in which a surface to which the warpage reduction member 130 of the substrate 100 is attached warps. That is, the warpage reduction member 130 may be provided to prevent or control warpage of the semiconductor package 1000A, and the warpage reduction member 130 may be provided at locations where the semiconductor package 1000A tends to warp or at other locations that may prevent or control warpage of the semiconductor package 1000A.

In one or more embodiments, the warpage reduction member 130 may be an adhesive film or an adhesive. For example, the adhesive film may be a polymer type adhesive film, and the adhesive may be a liquid adhesive. If the adhesive film or the adhesive is used, the warpage reduction member 130 with a high coefficient of thermal expansion may be provided.

In one or more embodiments, the warpage reduction member 130 with a relatively low coefficient of thermal expansion may be used, such that the semiconductor package 1000A having a tendency warp in a specific direction may be formed to warp less using a property in which a surface to which the warpage reduction member 130 of the substrate 100 is attached.

In one or more embodiments, the warpage reduction member 130 may include a resin and a filler. In order to provide the warpage reduction member 130 with a low coefficient of thermal expansion and rigidity, the filler included in the warpage reduction member 130 may include a material with the low coefficient of thermal expansion (for example, silica (SiO₂), alumina (Al₂O₃), or the like).

On the other hand, because the warpage reduction member 130 is exposed to the side surface 100S of the substrate 100, a material having corrosion resistance may be used. Therefore, in some examples, a metal material such as copper (Cu) with high corrosion resistance may not be used as a material for the warpage reduction member 130.

A thickness 130t (in the Z-direction of FIG. 1) of the warpage reduction member 130 may be about 5 μm to about 20 μm. The thickness 130t of the warpage reduction member 130 may be adjusted according to a thickness of the protective layer 121. If the thickness 130t of the warpage reduction member 130 is too low, it may be difficult to prevent warpage. Therefore, in one or more embodiments, the thickness 130t is about 5 μm or more.

A width 130w (in the X-direction of FIG. 1) of the warpage reduction member 130 may be about 50 μm to about 200 μm. In one or more embodiments, the width may refer to a width of the warpage reduction member 130 from an edge of the substrate. If the width 130w of the warpage reduction member 130 is too small, it may be difficult to prevent warpage of the semiconductor package 1000A, and if the width 130w of the warpage reduction member 130 is too large, a disposition space for the first connection pad 112P1 may be reduced. Thus, the width 130w may be implemented within the range of about 50 μm to about 200 μm.

In addition, the warpage reduction member 130 may delay transfer of a crack that may occur from the outside of the semiconductor package 1000A to the inside of the semiconductor package 1000A. The crack may occur as the result of a physical impact or the like is applied to the outside of the semiconductor package 1000A. For example, transfer of a crack occurring at an interface between the molding material 300 and the warpage reduction member 130 may be prevented or reduced as a stress is distributed at a region where the interface is bent.

Conductive bumps 140 may electrically connect the semiconductor package 1000A to other components, such as a main substrate on which the semiconductor package 1000A is mounted, another semiconductor package, and the like. The conductive bumps 140 may be disposed on the second surface 110S2 of the inner layer wiring structure 110 (for example, on the second connection pad 112P2 exposed through the opening of the second protective layer 122) to be electrically connected to the wiring layer 112. The conductive bumps 140 may be solder balls.

The semiconductor chip 200 may be disposed above the first protective layer 121 of the substrate 100 to be electrically connected to the substrate 100. The semiconductor chip 200 may have a connection pad 200P, and may be disposed such that a surface on which the connection pad 200P is disposed faces the substrate 100.

The semiconductor chip 200 may be flip-chip bonded above the substrate 100, and the conductive bump B may be disposed between the connection pad 200P of the semiconductor chip 200 and the first connection pad 112P1 of the substrate 100 to electrically connect them. The conductive bump B may be surrounded with an underfill resin UF filled between the semiconductor chip 200 and the substrate 100.

A type of the semiconductor chip 200 is not particularly limited, and the semiconductor chip 200 may be a logic chip, a memory chip, an application processor (AP) chip, or the like.

The semiconductor package 1000A may further include another electronic component such as a passive component, an active component, or the like. The additional electronic component may be disposed at a predetermined distance from the semiconductor chip 200 above the substrate 100 and may be encapsulated by the molding material 300 together with the semiconductor chip 200.

The molding material 300 may be disposed on the substrate 100 to encapsulate the semiconductor chip 200. Additionally, the molding material 300 may cover the warpage reduction member 130 disposed on the first protective layer 121. An insulating material such as an epoxy molding compound (EMC), an epoxy resin, or the like, may be used as a material of the molding material 300. The molding material 300 may be diced together with the substrate 100, and may be coplanar with the side surface 100S of the substrate 100.

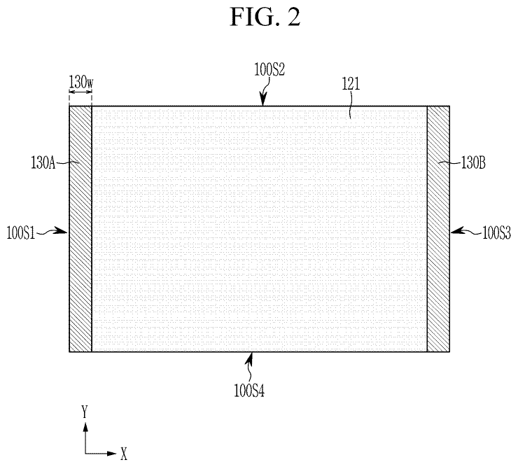

FIG. 2 is a plan view illustrating a layout of a warpage reduction member according to one or more embodiments.

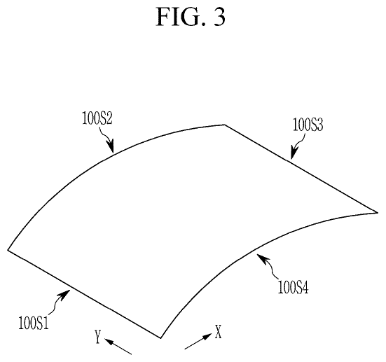

FIG. 3 is a diagram illustrating a warpage direction of the semiconductor package including the warpage reduction member having the layout of FIG. 2 according to one or more embodiments.

Referring to FIG. 2, the semiconductor package may include a first side surface 100S1 and a third side surface 100S3 that faces the first side surface 100S1, as well as a second side surface 100S2 and a fourth side surface 100S4 that faces the second side surface 100S2. The warpage reduction member 130 may include a first warpage reduction member 130A and a second warpage reduction member 130B respectively disposed along the first side surface 100S1 and the third side surface 100S3 of the substrate 100.

In one or more embodiments, the first warpage reduction member 130A and the second warpage reduction member 130B may be continuously disposed along the side surface 100S1 and 100S3 of the substrate 100. For example, the first warpage reduction member 130A may be continuously disposed along the Y-direction on the first side surface 100S1 of the substrate 100. Additionally, the second warpage reduction member 130B may be continuously disposed along the Y-direction on the third side surface 100S3 of the substrate 100. Additionally, the first warpage reduction member 130A and the second warpage reduction member 130B may be spaced apart from each other across the X-direction.

The warpage reduction member 130 may not be disposed on a second side surface 100S2 and a fourth side surface 100S4. Accordingly, the first protective layer 121 may be covered with the molding material 300 on the second side surface 100S2 and the fourth side surface 100S4 of the substrate 100.

In one or more embodiments, the width 130w of the warpage reduction member 130 may refer to a width along the X-direction.

The first side surface 100S1 and the third side surface 100S3 where the first warpage reduction member 130A and the second warpage reduction member 130B of the substrate 100 are disposed may be sides with a shorter length than the second side surface 100S2 and the fourth side surface 100S4.

Referring to FIG. 3, if the first warpage reduction member 130A and the second warpage reduction member 130B are disposed on the shorter side surfaces 100S1 and 100S3 (sides parallel to the Y-direction) of the semiconductor package 1000A, an artificial warpage may occur in a convex shape, such that the short side surfaces s 100S1 and 100S3 of the semiconductor package 1000A descend, and the long side surfaces 100S2 and 100S4 (side parallel to the X-direction) ascend. However, a specific warpage direction of the semiconductor package may vary depending on various factors, such as a physical property (e.g., a coefficient of thermal expansion), a volume, and the like of each of components constituting the semiconductor package.

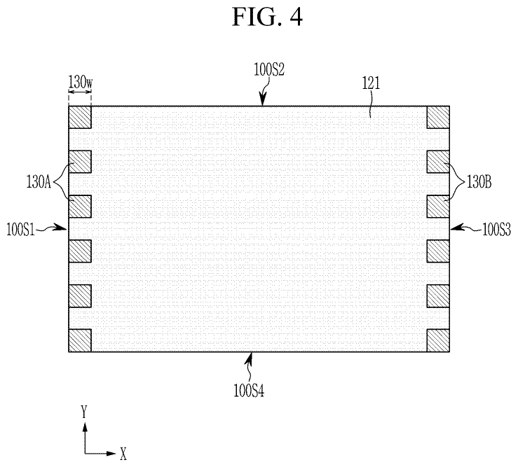

FIG. 4 is a plan view illustrating a layout of a warpage reduction member according to one or more embodiments.

In one or more embodiments, the first warpage reduction member 130A and the second warpage reduction member 130B may be discontinuously disposed along the side surfaces 100S1 and 100S3 of the substrate 100. That is, the first warpage reduction member 130A may include a plurality of warpage control portions spaced apart by predetermined intervals, and the second warpage reduction member 130B may include a plurality of warpage control portions spaced apart by predetermined intervals. For example, the first warpage reduction member 130A may be discontinuously disposed along the first side surface 100S1 of the substrate 100. Additionally, the second warpage reduction member 130B may be discontinuously disposed along the third side surface 100S3 of the substrate 100.

If the first warpage reduction member 130A and the second warpage reduction member 130B are discontinuously disposed, a surface area between the warpage reduction member 130 and the molding material 300 may be increased, such that adhesion between the warpage reduction member 130 and the molding material 300 is improved and flowability of the molding material 300 is secured in a unit level process. In addition, a path through which a crack occurring at an outer region of the package travels to an inner region thereof may be increased, such that progress of the crack is further delayed. The warpage reduction member 130 may be disposed at a corner region that is a region vulnerable to the crack.

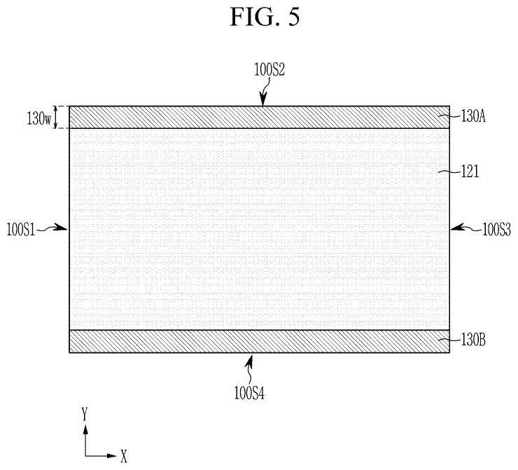

FIG. 5 is a plan view illustrating a layout of a warpage reduction member according to one or more embodiments.

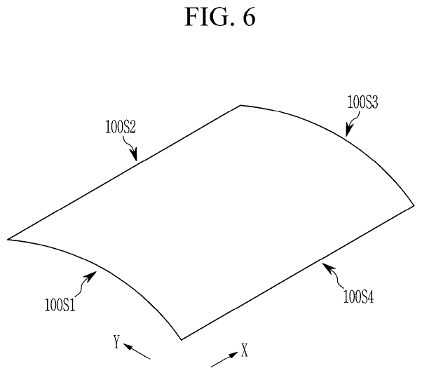

FIG. 6 is a diagram illustrating a warpage direction of a semiconductor package including a warpage reduction member having the layout of FIG. 5 according to one or more embodiments.

Referring to FIG. 5, the warpage reduction member 130 may include the first warpage reduction member 130A and the second warpage reduction member 130B disposed along the second side surface 100S2 and the fourth side surface 100S4 of the substrate 100.

In one or more embodiments, the first warpage reduction member 130A and the second warpage reduction member 130B may be continuously disposed along the side surfaces 100S2 and 100S4 of the substrate 100. For example, the first warpage reduction member 130A may be continuously disposed along the X-direction on the second side surface 100S2 of the substrate 100. Additionally, the second warpage reduction member 130B may be continuously disposed along the X-direction on the fourth side surface 100S4 of the substrate 100. Additionally, the first warpage reduction member 130A and the second warpage reduction member 130B may be spaced apart from each other across the Y-direction.

The warpage reduction member 130 may not be disposed on the first side surface 100S1 and the third side surface 100S3. Accordingly, the first protective layer 121 may be covered with the molding material 300 on the first side surface 100S1 and the third side surface 100S3 of the substrate 100.

In one or more embodiments, the width 130w of the warpage reduction member 130 may refer to a width along the Y-direction.

The second side surface 100S2 and the fourth side surface 100S4 where the first warpage reduction member 130A and the second warpage reduction member 130B of the substrate 100 are disposed may be sides with a longer length than the first side surface 100S1 and the third side surface 100S3.

Referring to FIG. 6, if the first warpage reduction member 130A and the second warpage reduction member 130B are disposed on the longer side surfaces 100S2 and 100S4 (sides parallel to the X-direction) of the semiconductor package 1000A, an artificial warpage may occur in a convex shape, such that the long side surfaces 100S2 and 100S4 of the semiconductor package 1000A descend, and the short side surfaces 100S1 and 100S3 (sides parallel to the Y-direction) ascend. However, a specific warpage direction of the semiconductor package may vary depending on various factors such as a physical property (e.g., a coefficient of thermal expansion), a volume, and the like of each of components constituting the semiconductor package.

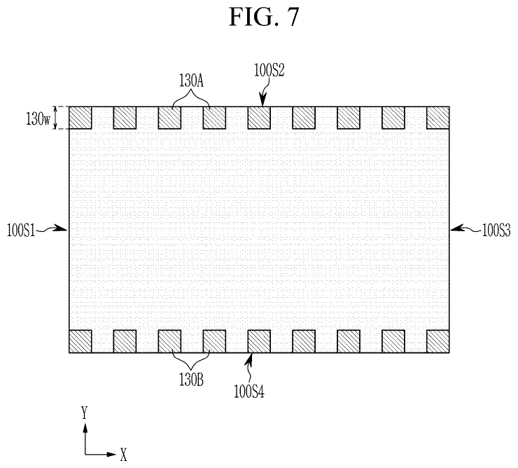

FIG. 7 is a plan view illustrating a layout of a warpage reduction member according to one or more embodiments.

In one or more embodiments, the first warpage reduction member 130A and the second warpage reduction member 130B may be discontinuously disposed along the side surface 100S2 and 100S4 of the substrate 100. That is, the first warpage reduction member 130A may include a plurality of warpage control portions spaced apart by predetermined intervals, and the second warpage reduction member 130B may include a plurality of warpage control portions spaced apart by predetermined intervals. For example, the first warpage reduction member 130A may be discontinuously disposed along the second side surface 100S2 of the substrate 100. Additionally, the second warpage reduction member 130B may be discontinuously disposed along the fourth side surface 100S4 of the substrate 100.

In order to prevent or control warpage of the semiconductor package (i.e., bending of the semiconductor package in a specific direction), the warpage reduction member 130 may be attached only to the long side or the short side of the semiconductor package 1000A, but embodiments are not limited thereto.

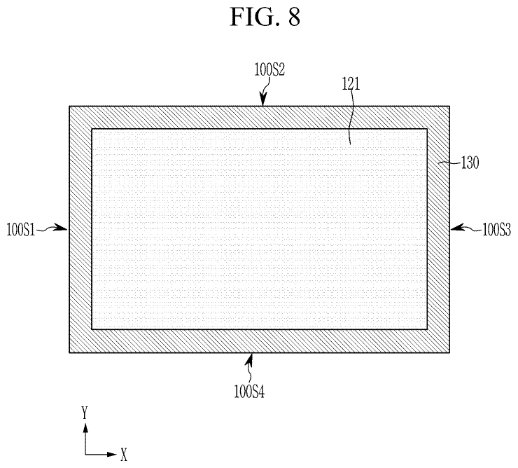

FIG. 8 is a plan view illustrating a layout of a warpage reduction member according to one or more embodiments. For example, as shown in FIG. 8, the warpage reduction member 130 may be disposed along an entire edge region 100ER of the substrate 100, and may be continuously disposed along an entire side surface 100S of the substrate 100 including the first side surface 100S1, the second side surface 100S2, the third side surface 100S3, and the fourth side surface 100S4.

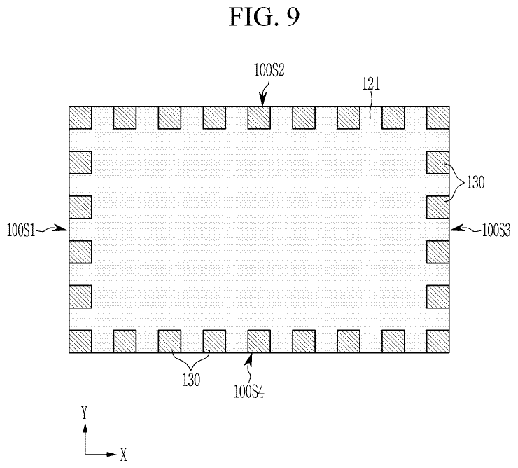

FIG. 9 is a plan view illustrating a layout of a warpage reduction member according to one or more embodiments. As shown in FIG. 9, the warpage reduction member 130 may be discontinuously disposed along an entire edge region 100ER of one surface of the first protective layer 121. That is, the warpage reduction member 130 may include a plurality of warpage control portions spaced apart by predetermined intervals along the entire edge region 100ER of the semiconductor package 1000A.

As another example, the warpage reduction member 130 may be disposed at a corner of the edge region 100ER of the substrate 100. Alternatively, the warpage reduction member 130 may be disposed at regions excluding the corner region.

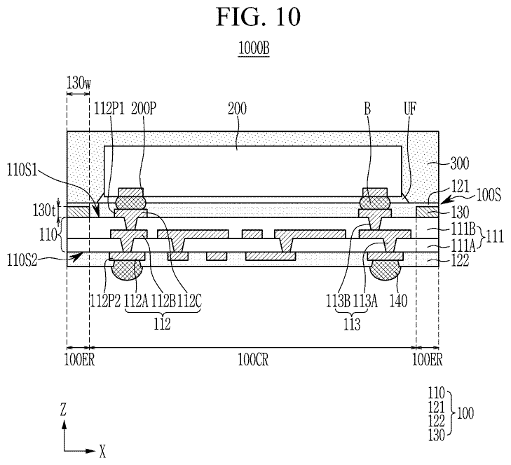

FIG. 10 is a cross-sectional view illustrating a semiconductor package according to one or more embodiments.

Referring to FIG. 10, in the semiconductor package 1000B, at least one warpage reduction member 130 may be disposed on first surface 110S1 of the inner layer wiring structure 110, and may be covered by the first protective layer 121.

The semiconductor package 1000B may be manufactured by forming the inner layer wiring structure 110 and forming the warpage reduction member 130 before the first protective layer 121 is formed on the first surface 110S1 of the inner layer wiring structure 110.

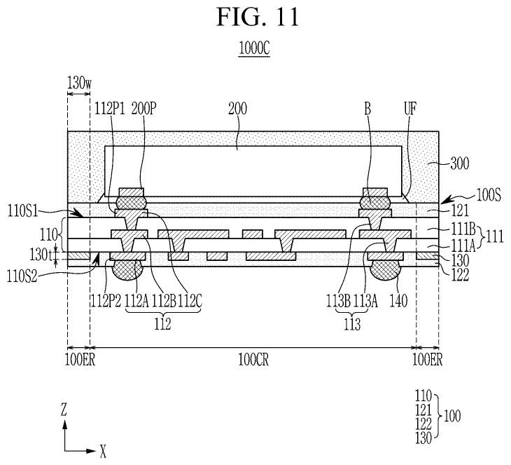

FIG. 11 is a cross-sectional view illustrating a semiconductor package according to one or more embodiments.

Referring to FIG. 11, in the semiconductor package 1000C, at least one warpage reduction member 130 may be disposed on the second surface 110S2 of the inner layer wiring structure 110, and may be covered by the second protective layer 122.

The warpage reduction member 130 may be disposed on the second surface 110S2 of the inner layer wiring structure 110 where the conductive bump 140 is disposed, such that a warpage direction of the package is controlled at a side adjacent to the conductive bump 140. Thus, a mounting defect of the package may be improved more efficiently.

If the warpage reduction member 130 of the semiconductor package 1000C is disposed along the entire edge region 100ER of the substrate 100 (e.g., the layout shown in FIG. 8 or FIG. 9), a lower side of the package where the warpage reduction member 130 is disposed may significantly and/or repeatedly expand and contract. Thus, an artificial warpage may occur in a convex shape in which the central region 100CR of the substrate 100 is raised in the Z-direction more than the edge region 100ER. However, a specific warpage direction of the semiconductor package may vary depending on various factors such as a physical property (e.g., a coefficient of thermal expansion), a volume, and the like of each of components constituting the semiconductor package.

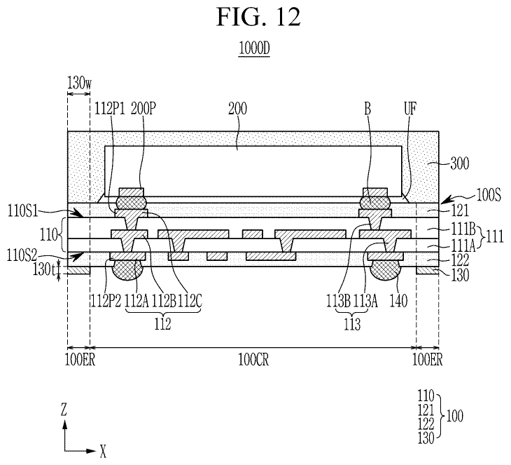

FIG. 12 is a cross-sectional view illustrating a semiconductor package according to one or more embodiments.

Referring to FIG. 12, in the semiconductor package 1000D, at least one warpage reduction member 130 may be disposed above the second surface 110S2 of the inner layer wiring structure 110 and on the second protective layer 122.

Similar to the semiconductor package 1000C, the warpage reduction member 130 may be disposed on the second surface 110S2 of the inner layer wiring structure 110 where the conductive bump 140 is disposed, such that a warpage direction of the package is controlled at a side adjacent to the conductive bump 140 and a mounting defect of the package is improved more efficiently.

If the warpage reduction member 130 of the semiconductor package 1000D is disposed along an entire region (i.e., the entire perimeter) of the edge region 100ER of the substrate 100 (e.g., the layout shown in FIG. 8 or FIG. 9), a lower side of the package where the warpage reduction member 130 is disposed may significantly and/or repeatedly expand and contract. Thus, an artificial warpage may occur in a convex shape in which the central region 100CR of the substrate 100 is raised in the Z-direction more than the edge region 100ER. However, a specific warpage direction of the semiconductor package may vary depending on various factors such as a physical property (e.g., a coefficient of thermal expansion), a volume, and the like of each of components constituting the semiconductor package.

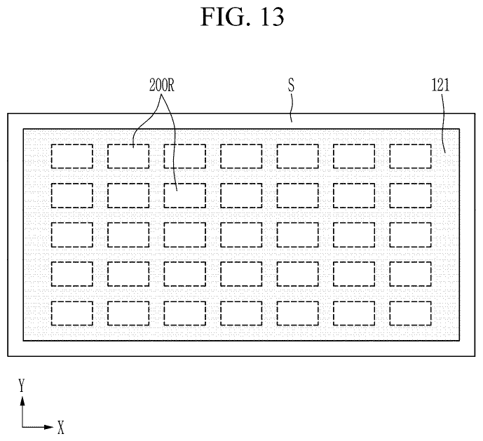

FIGS. 13 to 15 are plan views illustrating process of forming the warpage reduction member according to one or more embodiments.

In FIGS. 13 to 15, a process of forming the warpage reduction member 130 having the layout shown in FIG. 2 during a process of manufacturing the semiconductor package 1000A shown in FIG. 1 will be exemplarily described.

Referring to FIG. 13, a unit level base substrate in which the inner layer wiring structure 110, the first protective layer 121, and the second protective layer 122 are stacked above a substrate S may be prepared. The base substrate may have regions 200R where semiconductor chips 200 included in each semiconductor package are mounted in a later process.

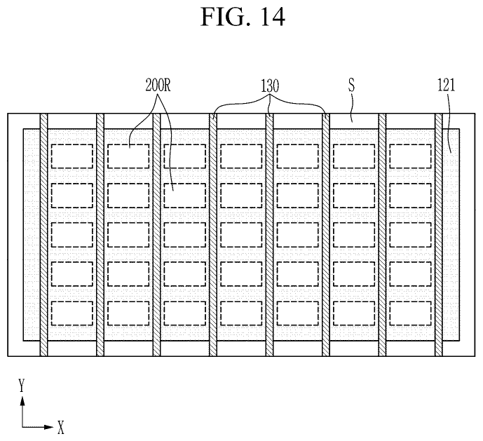

Referring to FIG. 14, warpage reduction members 130 may be formed on the first protective layer 121 of the base substrate. The warpage reduction members 130 may be formed to extend along the Y-direction between the regions 200R where the semiconductor chips 200 are mounted. For example, the warpage reduction member 130 may be formed by attaching an adhesive film or applying an adhesive on the first protective layer 121.

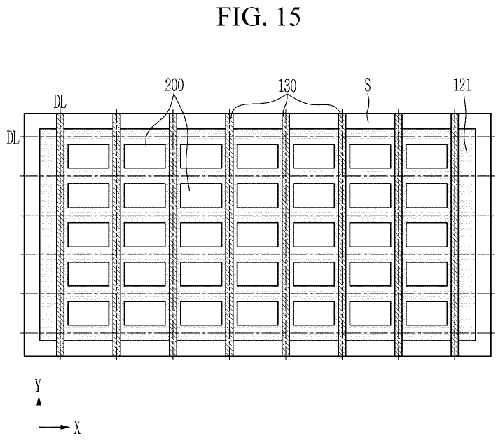

Referring to FIG. 15, an individual semiconductor package may be formed by disposing the semiconductor chip 200 above the first protective layer 121 where the warpage reduction member 130 is formed, encapsulating the semiconductor chip 200 with the molding material 300, and then dicing a unit-level package along a dicing line DL. The dicing line DL along the Y-direction may correspond to a central region of the warpage reduction member 130, such that the warpage reduction member 130 is disposed at the edge region 100ER of the substrate 100 after the dicing.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor package comprising:
a substrate comprising:
an inner layer wiring structure comprising an insulating layer and a wiring layer;
a first protective layer on a first surface of the inner layer wiring structure;
a second protective layer on a second surface of the inner layer wiring structure that is opposite to the first surface of the inner layer wiring structure, and
a first warpage control member and a second warpage reduction member on the first protective layer;
a semiconductor chip above the first protective layer and connected to the substrate; and
a molding material encapsulating the semiconductor chip,
wherein the first warpage reduction member is on a first side surface of the substrate,
wherein the second warpage reduction member is on a second side surface of the substrate, the second side surface being opposite to the first side surface, and
wherein the first protective layer is at least partially covered by the molding material on a third side surface of the substrate and a fourth side surface of the substrate, the fourth side surface being opposite to the third side surface.

2. The semiconductor package of claim 1, wherein at least one of the first warpage reduction member and the second warpage reduction member comprises an adhesive film or an insulating adhesive.

3. The semiconductor package of claim 1, wherein a coefficient of thermal expansion of at least one of the first warpage reduction member and the second warpage reduction member is 5 ppm/° C. to 150 ppm/° C.

4. The semiconductor package of claim 1, wherein the first warpage reduction member and the second warpage reduction member are continuously and respectively provided along the first side surface of the substrate and the second side surface of the substrate.

5. The semiconductor package of claim 1, wherein the first warpage reduction member comprises a plurality of warpage control portions spaced apart along the first side surface of the substrate, and
wherein the second warpage reduction member comprises a plurality of warpage control portions spaced apart along the second side surface of the substrate.

6. The semiconductor package of claim 1, wherein a thickness of at least one of the first warpage reduction member and the second warpage reduction member is 5 μm to 20 μm.

7. The semiconductor package of claim 1, wherein a width of at least one of the first warpage reduction member and the second warpage reduction member from an edge of the substrate is 50 μm to 200 μm.

8. The semiconductor package of claim 1, wherein at least one of the first warpage reduction member and the second warpage reduction member includes a resin and a filler.

9. The semiconductor package of claim 1, wherein the molding material at least partially covers at least one of the first warpage reduction member and the second warpage control member.

10. A semiconductor package comprising:
a substrate comprising:
an inner layer wiring structure comprising an insulating layer and a wiring layer;
at least one warpage reduction member above a first surface of the inner layer wiring structure;
a first protective layer on the first surface of the inner layer wiring structure and at least partially covering the at least one warpage reduction member; and
a second protective layer on a second surface of the inner layer wiring structure that is opposite to the first surface of the inner layer wiring structure;
a semiconductor chip above the first protective layer and connected to the substrate; and
a molding material that encapsulates the semiconductor chip,
wherein the at least one warpage reduction member is at an edge region of the substrate.

11. The semiconductor package of claim 10, wherein the at least one warpage reduction member comprises:
a first warpage reduction member along a first side surface of the substrate; and
a second warpage reduction member along a second side surface of the substrate.

12. The semiconductor package of claim 11, wherein the first warpage reduction member and the second warpage reduction member are continuously and respectively provided along the first side surface of the substrate and the second side surface of the substrate.

13. The semiconductor package of claim 11, wherein the first warpage reduction member comprises a plurality of warpage control portions spaced apart along the first side surface of the substrate, and
wherein the second warpage reduction member comprises a plurality of warpage control portions spaced apart along the second side surface of the substrate.

14. The semiconductor package of claim 10, wherein the at least one warpage reduction member comprises an adhesive film or an adhesive.

15. The semiconductor package of claim 10, wherein a coefficient of thermal expansion of the at least one warpage reduction member is 5 ppm/° C. to 150 ppm/° C.

16. The semiconductor package of claim 10, wherein the at least one warpage reduction member comprises a resin and a filler.

17. A semiconductor package comprising:
a substrate comprising:
an inner layer wiring structure comprising an insulating layer and a wiring layer;
at least one warpage reduction member above a first surface of the inner layer wiring structure; and
conductive bumps above the first surface of the inner layer wiring structure and connected to the wiring layer;
a semiconductor chip above a second surface of the inner layer wiring structure that is opposite to the first surface of the inner layer wiring structure, the semiconductor chip connected to the substrate; and
a molding material encapsulating the semiconductor chip,
wherein the at least one warpage reduction member is at an edge region of the substrate.

18. The semiconductor package of claim 17, further comprising a protective layer on the first surface of the inner layer wiring structure and at least partially covering the at least one warpage reduction member.

19. The semiconductor package of claim 17, further comprising a protective layer on the first surface of the inner layer wiring structure,
wherein the at least one warpage reduction member is on the protective layer.

20. The semiconductor package of claim 17, wherein the at least one warpage reduction member is along an entire perimeter of the edge region of the substrate.
